(19) United States
(12) Patent Application Publication
(10) Pub. No.: US 2024/0096649 A1
(43) Pub. Date: Mar. 21, 2024

(54) SEMICONDUCTOR PROCESS SYSTEM AND GAS TREATMENT METHOD

(71) Applicant: SAMSUNG ELECTRONICS CO., LTD., Suwon-si (KR)

(72) Inventors: Wonsu LEE, Suwon-si (KR); Hyunseok KIM, Suwon-si (KR); Jungdae PARK, Suwon-si (KR); Kimoon LEE, Suwon-si (KR); Jong-San CHANG, Suwon-si (KR)

(73) Assignee: SAMSUNG ELECTRONICS CO., LTD., Suwon-si (KR)

(21) Appl. No.: 18/368,422

(22) Filed: Sep. 14, 2023

(30) Foreign Application Priority Data
Sep. 16, 2022 (KR) 10-2022-0116808
Jan. 19, 2023 (KR) 10-2023-0008163

(51) Int. Cl. H01L 21/67; H05H 1/24; H05H 1/26

(52) U.S. Cl. CPC H01L 21/67017; H05H 1/2406; H05H 1/26; H05H 2245/17

(57) ABSTRACT

A gas treatment method, including: treating an exhaust gas discharged from a semiconductor process chamber using a gas treatment system; and discharging the treated exhaust gas, wherein the treating of the exhaust gas includes: operating a first thermal oxidizer to treat the exhaust gas discharged from the semiconductor process chamber, the first thermal oxidizer being connected to the semiconductor process chamber and allowing the treated exhaust gas to pass through a plasma processing apparatus connected to the first thermal oxidizer; stopping the operation of the first thermal oxidizer to perform maintenance on the first thermal oxidizer; and wherein the stopping the operation of the first thermal oxidizer comprises: performing maintenance on the first thermal oxidizer; and operating the plasma processing apparatus to treat the exhaust gas discharged from the semiconductor process chamber

### CROSS-REFERENCE TO RELATED APPLICATIONS

This application claims priority under 35 U.S.C § 119 to Korean Patent Application No. 10-2022-0116808 filed on Sep. 16, 2022 and Korean Patent Application No. 10-2023-0008163 filed on Jan. 19, 2023, in the Korean Intellectual Property Office, the disclosures of which are hereby incorporated by reference in their entirety.

### BACKGROUND

The disclosure relates to a semiconductor process system and a gas treatment method, and more particularly, to a semiconductor process system and a gas treatment method that can treat an exhaust gas even when a thermal oxidizer does not operate.

A semiconductor device may be fabricated by using various processes. For example, a semiconductor device may be manufactured by allowing a silicon wafer to undergo a photolithography process, an etching process, a deposition process, and so forth. Various chemical materials may be used in such processes. The chemical material may be exhausted in gaseous state. For safety, the chemical material may be treated before exhaustion from semiconductor process facilities to the atmosphere. Various gas treatment apparatus may be used to treat the chemical material.

### SUMMARY

Provided is a semiconductor process system and a gas treatment method that can treat an exhaust gas during maintenance of a thermal oxidizer.

Also provided is a semiconductor process system and a gas treatment method that can save power consumption.

Also provided is a semiconductor process system and a gas treatment method that can prevent release of harmful substances even in emergency situation.

Additional aspects will be set forth in part in the description which follows and, in part, will be apparent from the description, or may be learned by practice of the presented embodiments.

In accordance with an aspect of the disclosure, a gas treatment method includes treating an exhaust gas discharged from a semiconductor process chamber using a gas treatment system; and discharging the treated exhaust gas, wherein the treating of the exhaust gas includes: operating a first thermal oxidizer to treat the exhaust gas discharged from the semiconductor process chamber, the first thermal oxidizer being connected to the semiconductor process chamber and allowing the treated exhaust gas to pass through a plasma processing apparatus connected to the first thermal oxidizer; stopping the operation of the first thermal oxidizer to perform maintenance on the first thermal oxidizer; and wherein the stopping the operation of the first thermal oxidizer comprises: performing maintenance on the first thermal oxidizer; and operating the plasma processing apparatus to treat the exhaust gas discharged from the semiconductor process chamber.

In accordance with an aspect of the disclosure, a gas treatment method includes treating an exhaust gas discharged from a semiconductor process chamber using a gas treatment system; and discharging the treated exhaust gas, wherein the treating of the exhaust gas includes operating a first thermal oxidizer to treat the exhaust gas discharged from the semiconductor process chamber, the first thermal oxidizer being connected to the semiconductor process chamber; and operating a plasma processing apparatus to treat the exhaust gas discharged from the semiconductor process chamber, the plasma processing apparatus being connected to the semiconductor process chamber in parallel to the first thermal oxidizer.

In accordance with an aspect of the disclosure, a semiconductor process system includes a semiconductor process chamber; and a gas treatment system configured to treat an exhaust gas discharged from the semiconductor process chamber, wherein the gas treatment system includes: a thermal oxidizer configured to treat the exhaust gas discharged from the semiconductor process chamber, the thermal oxidizer being connected to the semiconductor process chamber; and a plasma processing apparatus configured to treat the exhaust gas discharged from the semiconductor process chamber.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 illustrates a schematic diagram showing a semiconductor process system according to an embodiment;

FIG. 2 illustrates a cross-sectional view showing a thermal oxidizer according to an embodiment;

FIG. 3 illustrates a cross-sectional view showing a plasma processing apparatus according to an embodiment;

FIGS. 4A to 4C illustrate flow charts showing a gas treatment method according to an embodiment;

FIGS. 5 to 8 illustrate diagrams showing example operations of a gas treatment method, according to embodiments;

FIG. 9 illustrates a schematic diagram showing a semiconductor process system according to an embodiment;

FIG. 10 illustrates a perspective view showing a plasma processing apparatus according to an embodiment;

FIG. 11 illustrates an enlarged perspective view partially showing a plasma processing apparatus according to an embodiment;

FIG. 12 illustrates a schematic diagram showing a semiconductor process system according to an embodiment;

FIGS. 13A to 13C illustrate flow charts showing a gas treatment method according to an embodiment;

FIGS. 14 and 15 illustrate diagrams showing example operations of a gas treatment method, according to embodiments;

FIG. 16 illustrates a schematic diagram showing a semiconductor process system according to an embodiment;

FIGS. 17 to 19 illustrate diagrams showing example operations of a gas treatment method, according to embodiments;

### DETAILED DESCRIPTION OF EMBODIMENTS

The embodiments described herein are example embodiments, and thus, the disclosure is not limited thereto and may be realized in various other forms. Like reference numerals may indicate like components throughout the description. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

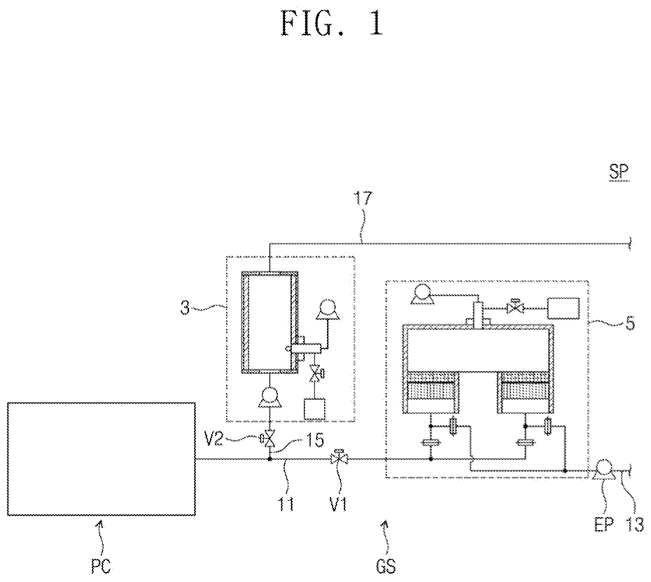

FIG. 1 illustrates a schematic diagram showing a semiconductor process system according to some embodiments.

Referring to FIG. 1, a semiconductor process system SP may be provided. The semiconductor process system SP may perform a process to fabricate a semiconductor device. For example, the semiconductor process system SP may fabricate a semiconductor device by allowing a substrate to undergo at least one of a deposition process, an exposure process, and an etching process. The term “substrate” may refer to a silicon (Si) wafer, but embodiments are not limited thereto. In addition, the semiconductor process system SP may treat a gas discharged from a process to fabricate a semiconductor device. The semiconductor process system SP may include a semiconductor process chamber PC and a gas treatment system GS.

The semiconductor process chamber PC may perform a semiconductor process. The semiconductor process may refer to a deposition process, an exposure process, and/or an etching process performed on a substrate. For example, the semiconductor process chamber PC may include at least one of a deposition device, an exposure device, and an etching device. Various kinds of fluid may be used in the semiconductor process chamber PC. A gas may be discharged from the semiconductor process chamber PC. An exhaust gas may be defined to indicate the gas discharged from the semiconductor process chamber PC. The exhaust gas may include a harmful substance. For example, the exhaust gas may include a volatile organic compound (VOC). In embodiments, the exhaust gas may include a low-concentration VOC. The phrase “low-concentration VOC” may refer to a VOC which has a concentration in a range of about 100 ppm to about 2,000 ppm. The low-concentration VOC may be removed by thermal oxidation.

The gas treatment system GS may be associated with the semiconductor process chamber PC. The gas treatment system GS may treat a gas discharged from the semiconductor process chamber PC. For example, the gas treatment system GS may treat the low-concentration VOC discharged from the semiconductor process chamber PC. The gas treatment system GS may include a connection line 11, a thermal oxidizer 5, a first valve V1, a first exhaust line 13, a branch line 15, a plasma processing apparatus 3, a second valve V2, and a second exhaust line 17.

The connection line 11 may be connected to the semiconductor process chamber PC. The exhaust gas released from the semiconductor process chamber PC may be discharged through the connection line 11.

The thermal oxidizer 5 may be connected to the connection line 11. The exhaust gas released from the semiconductor process chamber PC may be introduced through the connection line 11 to the thermal oxidizer 5. The thermal oxidizer 5 may treat the exhaust gas. For example, the thermal oxidizer 5 may oxidize the low-concentration VOC in the exhaust gas. The thermal oxidizer 5 may generate a flame or flames to treat the exhaust gas. The low-concentration VOC in the exhaust gas may be oxidized by a flame or flames generated from the thermal oxidizer 5. The thermal oxidizer 5 may include a configuration that generates a flame or flames. For example, the thermal oxidizer 5 may include a regenerative catalytic oxidizer (RCO), a regenerative thermal oxidizer (RTO), and/or a catalytic thermal oxidizer (CTO). An example in which a regenerative catalytic oxidizer (RCO) is used as the thermal oxidizer 5 is provided below.

The first valve V1 may be positioned on the connection line 11. The first valve V1 may be positioned between the semiconductor process chamber PC and the thermal oxidizer 5. The first valve V1 may be opened or closed to control a flow of the exhaust gas from the semiconductor process chamber PC to the thermal oxidizer 5. The first valve V1 may be an automatic valve, but embodiments are not limited thereto.

The first exhaust line 13 may be connected to the thermal oxidizer 5. The first exhaust line 13 may outwardly discharge the exhaust gas that has been treated in the thermal oxidizer 5. An exhaust pump EP on the first exhaust line 13 may pump the exhaust gas. The first exhaust line 13 may immediately discharge the exhaust gas that has been treated in the thermal oxidizer 5 into the environment. In embodiments, the exhaust gas that has been treated in the thermal oxidizer 5 may be discharged into the environment through a separate device that is connected to an end of the first exhaust line 13.

The branch line 15 may be connected to the connection line 11. The branch line 15 may be branched from the connection line 11. The branch line 15 may be connected to the connection line 11 between the semiconductor process chamber PC and the first valve V1.

The plasma processing apparatus 3 may be connected to the branch line 15. The exhaust gas discharged from the semiconductor process chamber PC may be introduced through the branch line 15 into the plasma processing apparatus 3. Because the branch line 15 is branched from the connection line 11, the plasma processing apparatus 3 connected to an end of the branch line 15 may be considered to be arranged in parallel to the thermal oxidizer 5 connected to an end of the connection line 11. For example, the plasma processing apparatus 3 and the thermal oxidizer 5 may be considered to be connected to the semiconductor process chamber PC in parallel to each other. For example, the plasma processing apparatus 3 and the thermal oxidizer 5 may be disposed in parallel to each other with respect to the semiconductor process chamber PC. Therefore, the exhaust gas discharged from the semiconductor process chamber PC may move to only one of the plasma processing apparatus 3 and the thermal oxidizer 5.

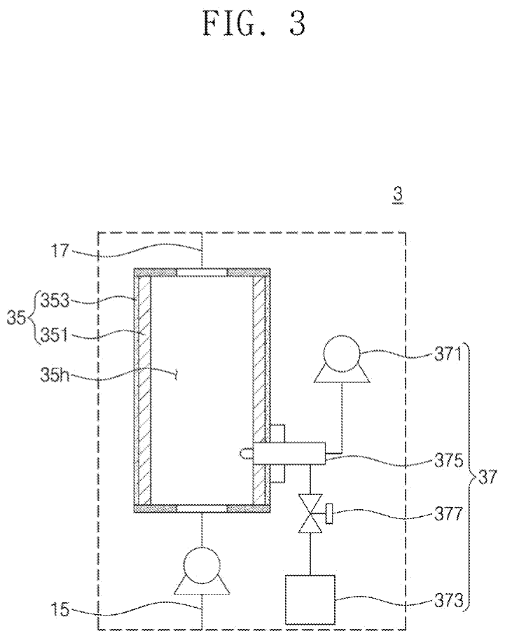

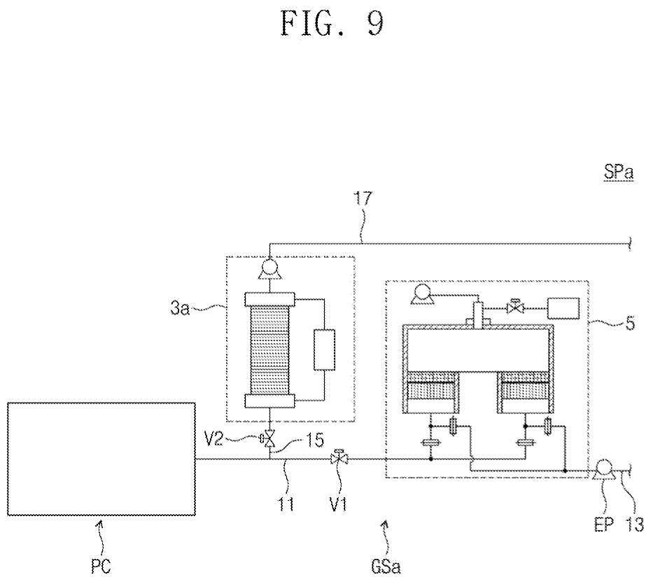

The plasma processing apparatus 3 may treat the exhaust gas. For example, the plasma processing apparatus 3 may oxidize the low-concentration VOC in the exhaust gas. A plasma may be produced during the procedure in which the plasma processing apparatus 3 treats the exhaust gas. For example, the plasma processing apparatus 3 may use the plasma to form a flame or flames. The plasma processing apparatus 3 may include a plasma torch oxidizer. The plasma torch oxidizer may use plasma torch to form a flame or flames. An example of this is discussed in greater detail below with reference to FIG. 3. Although the plasma processing apparatus 3 is described above as a plasma torch oxidizer, but embodiments are not limited thereto. For example, the plasma processing apparatus 3 may include a dielectric barrier discharge (DBD) plasma reactor. An example in which the plasma processing apparatus 3 is a DBD plasma reactor is described below with reference to FIGS. 9 to 11. In embodiments, the plasma processing apparatus 3 may be or include a corona plasma reactor.

The second valve V2 may be positioned on the branch line 15. The second valve V2 may be positioned between the semiconductor process chamber PC and the plasma processing apparatus 3. The second valve V2 may be opened or closed to control a flow of the exhaust gas from the semiconductor process chamber PC to the plasma processing apparatus 3. The second valve V2 may be an automatic valve, but embodiments are not limited thereto.

The second exhaust line 17 may be connected to the plasma processing apparatus 3. The second exhaust line 17 may outwardly discharge the exhaust gas that has been treated in the plasma processing apparatus 3. The second exhaust line 17 may immediately discharge the exhaust gas that has been treated in the plasma processing apparatus 3 into the surrounding environment, for example at least one of the environment surrounding the semiconductor process system SP, the environment surrounding the gas treatment system GS, and the environment surrounding the plasma processing apparatus 3. In embodiments, the exhaust gas that has been treated in the plasma processing apparatus 3 may be discharged into the surrounding environment through a separate device that is connected to an end of the second exhaust line 17.

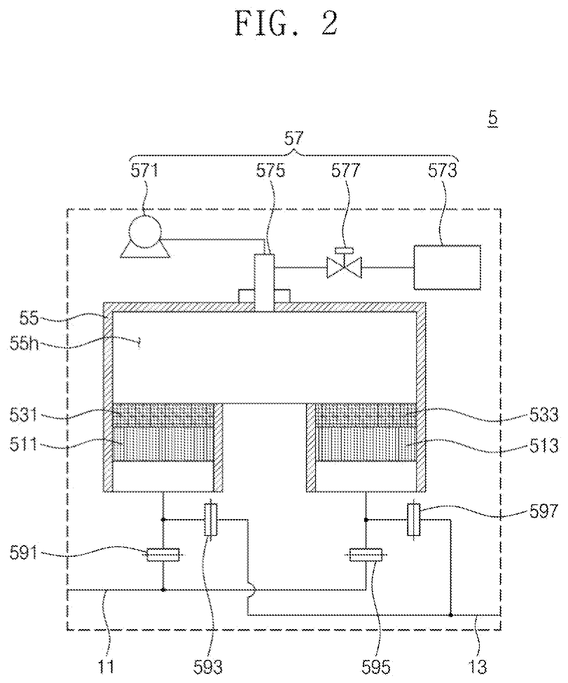

FIG. 2 illustrates a cross-sectional view showing a thermal oxidizer according to some embodiments.

Referring to FIG. 2, the thermal oxidizer 5 may include, for example, a 2-bed regenerative catalytic oxidizer. The thermal oxidizer 5 may decompose a specific constituent in the exhaust gas. For example, the thermal oxidizer 5 may decompose the VOC contained in the exhaust gas. The exhaust gas may be introduced through the connection line 11 into the thermal oxidizer 5. In addition, the exhaust gas may be released through the first exhaust line 13 from the thermal oxidizer 5. The thermal oxidizer 5 may include a first heat storage medium 511, a first catalytic layer 531, a second heat storage medium 513, a second catalytic layer 533, a combustion chamber 55, a combustion device 57, a first damper 591, a second damper 593, a third damper 595, and a fourth damper 597.

The first heat storage medium 511 may store and/or release heat. For example, the first heat storage medium 511 may temporarily store heat. When the exhaust gas passing through the first heat storage medium 511 has a temperature less than that of the first heat storage medium 511, the first heat storage medium 511 may release heat to the exhaust gas. When the exhaust gas passing through the first heat storage medium 511 has a temperature greater than that of the first heat storage medium 511, the exhaust gas may release heat to the first heat storage medium 511. The first heat storage medium 511 may have a porous structure. For example, the first heat storage medium 511 may have a honeycomb structure, embodiments are not limited thereto. The first heat storage medium 511 may include an excellent refractory material. For example, the first heat storage medium 511 may include a ceramic.

The first catalytic layer 531 may be positioned on the first heat storage medium 511. The first catalytic layer 531 may include a catalyst for a decomposition reaction of a specific constituent in the exhaust gas. For example, the first catalytic layer 531 may include Co or ZrO₂—Al₂O₃, but embodiments are not limited thereto.

The second heat storage medium 513 may be spaced apart in a horizontal direction from the first heat storage medium 511. The combustion chamber 55 may be positioned at least partially between the second heat storage medium 513 and the first heat storage medium 511. The second heat storage medium 513 may include a material and a configuration substantially the same as or similar to those of the first heat storage medium 511.

The second catalytic layer 533 may be positioned on the second heat storage medium 513. The second catalytic layer 533 may be spaced apart in a horizontal direction from the first catalytic layer 531. The second catalytic layer 533 may include a material and a configuration substantially the same as those of the first catalytic layer 531.

The combustion chamber 55 may provide a combustion space 55h. The combustion space 55h may be positioned between the first catalytic layer 531 and the second catalytic layer 533. Therefore, a gas that has passed through the first catalytic layer 531 may move through the combustion space 55h to the second catalytic layer 533. A combustion reaction may be performed or may occur in the combustion chamber 55.

The combustion device 57 may include a combustion air blower 571, a liquefied natural gas (LNG) supply device 573, an LNG burner 575, and a fuel control valve 577. The combustion air blower 571 may supply air required for combustion. The LNG supply device 573 may supply fuel required for combustion. The LNG burner 575 may use air and fuel to include a combustion reaction. The LNG burner 575 may be or include a plasma assisted LNG burner. In this case, fuel consumption may be reduced. The LNG burner 575 may cause a combustion reaction in the combustion chamber 55. Therefore, the exhaust gas that passes through the combustion chamber 55 may be heated to high temperature. The fuel control valve 577 may be positioned between the LNG supply device 573 and the LNG burner 575. The fuel control valve 577 may be opened or closed to control a flow of fuel from the LNG supply device 573 to the LNG burner 575.

The first damper 591 may be positioned between the first heat storage medium 511 and the connection line 11. The second damper 593 may be positioned between the first heat storage medium 511 and the first exhaust line 13. The third damper 595 may be positioned between the second heat storage medium 513 and the first exhaust line 13. The fourth damper 597 may be positioned between the second heat storage medium 513 and the connection line 11.

Although the thermal oxidizer 5 is described above as a 2-bed regenerative catalytic oxidizer, embodiments are not limited thereto. For example, the thermal oxidizer 5 may be or include a 3-bed regenerative catalytic oxidizer. As another example, the thermal oxidizer 5 may be or include a regenerative thermal oxidizer (RTO) or a catalytic thermal oxidizer (CTO).

FIG. 3 illustrates a cross-sectional view showing a plasma processing apparatus according to some embodiments.

Referring to FIG. 3, the plasma processing apparatus 3 may be or include a plasma torch oxidizer. The exhaust gas may be introduced through the branch line 15 to the plasma processing apparatus 3. In addition, the exhaust gas may be released through the second exhaust line 17 from the plasma processing apparatus 3. The exhaust gas may be treated in the plasma processing apparatus 3. The plasma processing apparatus 3 may decompose a specific constituent in the exhaust gas. For example, the plasma processing apparatus 3 may decompose the VOC contained in the exhaust gas. In embodiments, the plasma processing apparatus 3 may use plasma torch to form a flame or flames to decompose the VOC contained in the exhaust gas. The plasma processing apparatus 3 may include a reserve combustion chamber 35 and a reserve combustion device 37.

The reserve combustion chamber 35 may provide a reserve combustion space 35h. The reserve combustion space 35h may be connected to each of the branch line 15 and the second exhaust line 17. The reserve combustion chamber 35 may include an inner housing 351 and an outer housing 353. An inner surface of the inner housing 351 may define the reserve combustion space 35h. The inner housing 351 may include a ceramic, but embodiments are not limited thereto. The outer housing 353 may surround the inner housing 351. The outer housing 353 may include, for example, carbon steel and/or stainless steel (SUS).

The reserve combustion device 37 may provide the reserve combustion space 35h with a flame or flames. The reserve combustion device 37 may include a reserve combustion air blower 371, a reserve fuel supply device 373, a plasma torch 375, and a reserve fuel control valve 377. The reserve combustion air blower 371 may supply air required for combustion. The reserve fuel supply device 373 may supply fuel required for combustion. For example, the reserve fuel supply device 373 may supply a liquefied natural gas (LNG). The plasma torch 375 may form a flame or flames. For example, the plasma torch 375 may use plasma to form a flame or flames. The plasma torch 375 may include an arc plasma discharge torch and/or a microwave plasma discharge torch. The reserve fuel control valve 377 may be positioned between the reserve fuel supply device 373 and the plasma torch 375. The reserve fuel control valve 377 may be opened or closed to control a flow of fuel from the reserve fuel supply device 373 to the plasma torch 375.

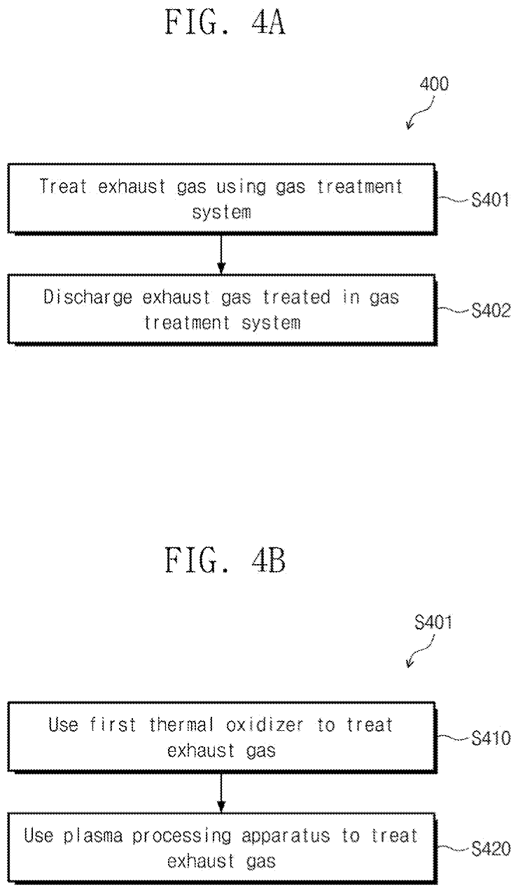

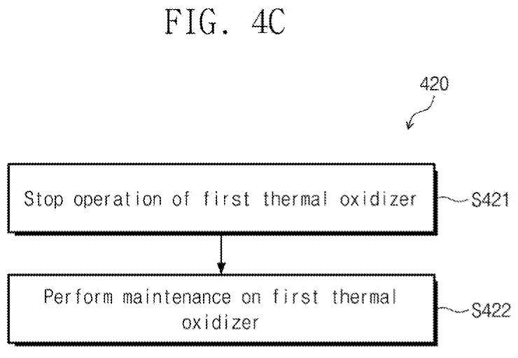

FIGS. 4A to 4C illustrate flow charts showing a gas treatment method according to some embodiments.

Referring to FIGS. 4A to 4C, a gas treatment method 400 may be provided. The gas treatment method 400 may be a method of treating a gas by using the gas treatment system GS discussed with reference to FIGS. 1 to 3. As shown in FIG. 4A, the gas treatment method 400 may include allowing a gas treatment system to treat an exhaust gas at operation S401, and discharging the exhaust gas that has been treated in the gas treatment system at operation S402.

FIG. 4B shows an example of operation S401, according to embodiments. As shown in FIG. 4B, operation S401 may include allowing a first thermal oxidizer to treat the exhaust gas at operation S410, and allowing a plasma processing apparatus to treat the exhaust gas at operation S420.

FIG. 4C shows an example of operation S420, according to embodiments. As shown in FIG. 4C, the operation S420 may include stopping an operation of the first thermal oxidizer at operation S421, and performing maintenance on the first thermal oxidizer at operation S422.

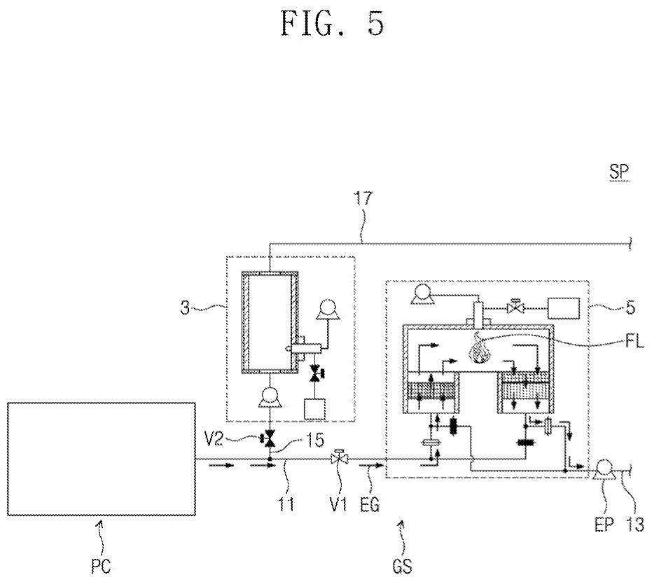

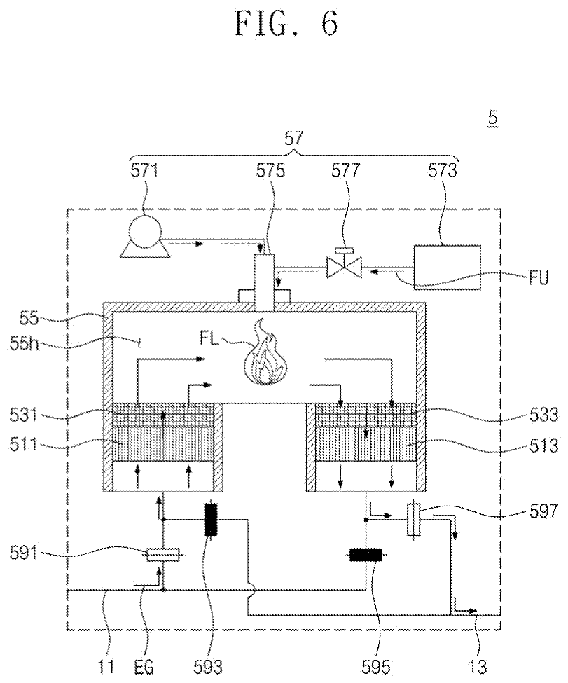

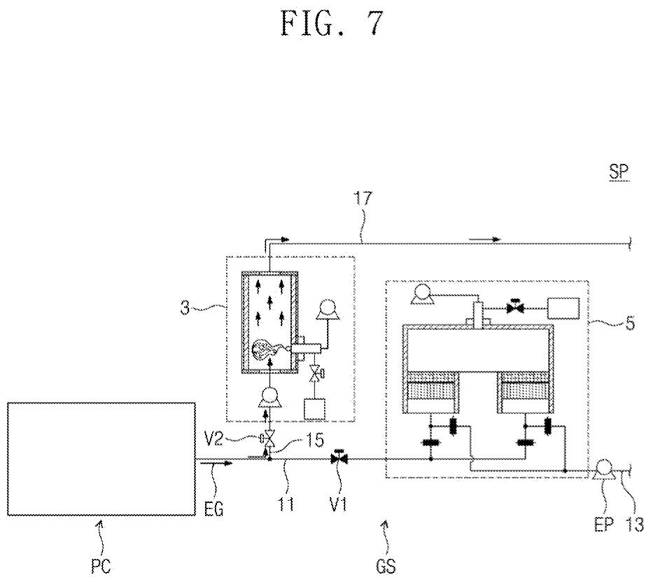

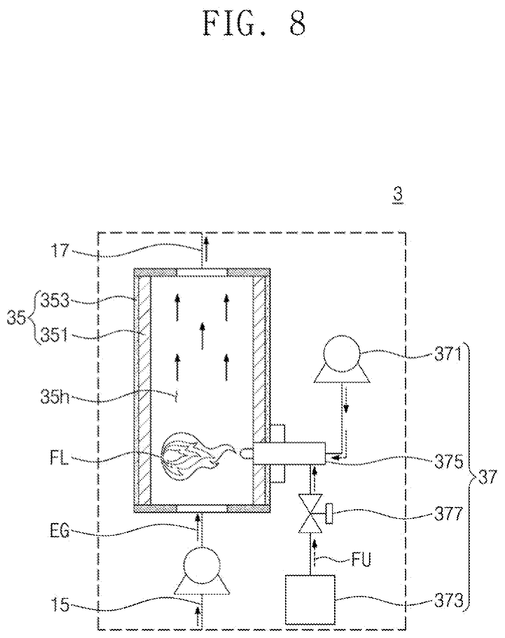

An example of the gas treatment method 400 of FIGS. 4A to 4C is discussed below with reference to FIGS. 5 to 8.

FIGS. 5 to 8 illustrate diagrams showing example operations of a gas treatment method according to the flow charts of FIGS. 4A to 4C.

Referring to FIGS. 4A to 4C, 5, and 6, operation S410 may include allowing the thermal oxidizer 5 to receive an exhaust gas EG discharged from the semiconductor process chamber PC. The exhaust gas EG may move to the thermal oxidizer 5 through the connection line 11 and the first valve V1. In operation S410, the second valve V2 may be closed. In addition, the plasma processing apparatus 3 may not be operated during operation S410. The thermal oxidizer 5 may operate to treat the exhaust gas EG. For example, as illustrated in FIG. 6, the first damper 591 and the fourth damper 597 may be opened. At the same time, the second damper 593 and the third damper 595 may be closed. Therefore, the exhaust gas EG may sequentially pass through the first heat storage medium 511, the first catalytic layer 531, the combustion space 55h, the second catalytic layer 533, and the second heat storage medium 513.

When the exhaust gas EG passes through the first heat storage medium 511, the exhaust gas EG may increase in temperature. When the exhaust gas EG having an increased temperature passes through the first catalytic layer 531, the VOC in the exhaust gas EG may be decomposed. The combustion device 57 may form a flame FL in the combustion space 55h. When the exhaust gas EG passes through the combustion space 55h, the flame FL may increase the temperature of the exhaust gas EG. When the exhaust gas EG passes through the second catalytic layer 533, the VOC in the exhaust gas EG may be decomposed. When the exhaust gas EG passes through the second heat storage medium 513, the exhaust gas EG may decrease in temperature. The exhaust gas EG that has passed through the second heat storage medium 513 may be released through the first exhaust line 13.

As time elapses, the first damper 591 and the fourth damper 597 may be closed. At the same time, the second damper 593 and the third damper 595 may be opened. Therefore, the exhaust gas EG may sequentially pass through the second heat storage medium 513, the second catalytic layer 533, the combustion space 55h, the first catalytic layer 531, and the first heat storage medium 511. In this case, the exhaust gas EG may flow in a reverse direction.

Referring to FIGS. 4, 7, and 8, operation S421 may include allowing the exhaust gas EG discharged from the semiconductor process chamber PC to enter the plasma processing apparatus 3 through the branch line 15 and the second valve V2. In operation S421, the first valve V1 may be closed. The flame FL may be formed by the plasma torch 375 of the plasma processing apparatus 3. The flame FL may treat the exhaust gas EG that passes through the reserve combustion space 35h.

Operation S422 may be performed when an operation of the thermal oxidizer 5 is stopped. For example, while the plasma processing apparatus 3 treats the exhaust gas EG, maintenance may be performed on the thermal oxidizer 5. For example, the maintenance which may be performed at operation S422 may include replacing and/or maintaining a heat storage medium in the thermal oxidizer 5.

According to a semiconductor process system and a gas treatment method in accordance with some embodiments, even while a thermal oxidizer is stopped in operation for maintenance, it may be possible to treat an exhaust gas discharged from a semiconductor process chamber. Therefore, harmful substances may be prevented from being discharged to the environment even when maintenance is performed on the thermal oxidizer. In embodiments, even in the emergency case where the thermal oxidizer is unexpectedly interrupted in operation, harmful substances may be prevented from being released.

According to a semiconductor process system and a gas treatment method in accordance with some embodiments, it may be possible to use a plasma processing apparatus as a reserve apparatus, or for example as a backup apparatus. The plasma processing apparatus may not require a pre-heating procedure to treat the exhaust gas. Thus, in case of emergency, the exhaust gas may be immediately treated. In addition, the plasma processing apparatus may be used as a reserve, and the thermal oxidizer may be used normally to treat the exhaust gas, which may result in a reduction in power consumption. Accordingly, cost may be saved

FIG. 9 illustrates a schematic diagram showing a semiconductor process system according to some embodiments.

In the following, redundant or duplicative description which is substantially the same as, or similar to, description provided above with reference to FIGS. 1 to 8 may be omitted.

Referring to FIG. 9, a semiconductor process system SPa may be provided. The semiconductor process system SPa may include a semiconductor process chamber PC and a gas treatment system GSa. The gas treatment system GSa may include a plasma processing apparatus 3a. The plasma processing apparatus 3a of FIG. 9 may include a DBD plasma reactor.

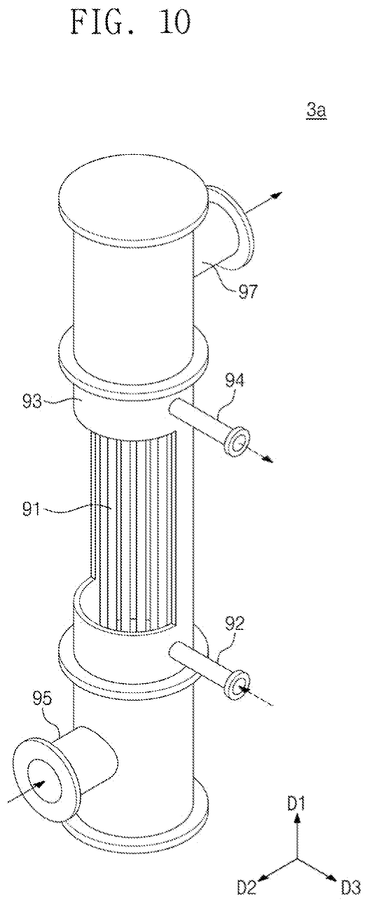

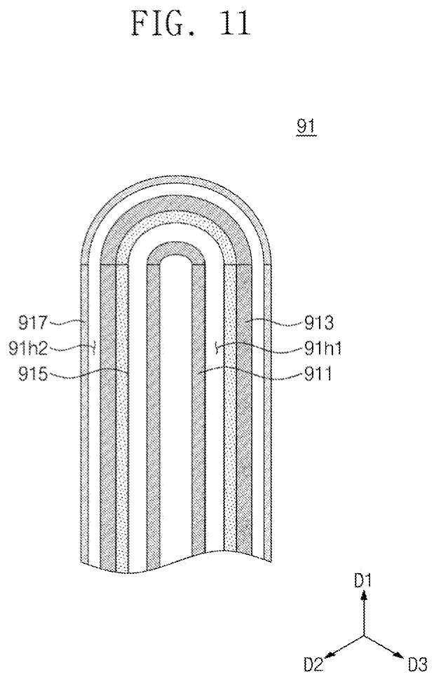

FIG. 10 illustrates a perspective view showing a plasma processing apparatus according to some embodiments. FIG. 11 illustrates an enlarged perspective view partially showing a plasma processing apparatus according to some embodiments.

As used herein, D1 may indicate or refer to a first direction, D2 may indicate or refer to a second direction that intersects the first direction D1, and D3 may indicate or refer to a third direction that intersects the first direction D1 and the second direction D2.

Referring to FIG. 10, the plasma processing apparatus 3a may decompose a specific constituent in an exhaust gas. For example, the plasma processing apparatus 3a may decompose a VOC contained in the exhaust gas. The plasma processing apparatus 3a may include a plasma generator 91, a plasma reaction housing 93, a second gas inlet 95, a second gas outlet 97, a cooling water inlet 92, and a cooling water outlet 94.

The plasma generator 91 may extend in the first direction D1. Plasma may be produced in the plasma generator 91. A VOC may be decomposed while a gas passes through the plasma generator 91. In embodiments, the plasma processing apparatus 3a may include a plurality of plasma generators 91. The plurality of plasma generators 91 may be spaced apart from each other in the second direction D2 and/or the third direction D3. For convenience of description, a single plasma generator 91 is described below, but embodiments are not limited thereto.

The plasma reaction housing 93 may surround the plasma generator 91. The second gas inlet 95 may be connected to one end of the plasma generator 91. A gas may be introduced through the second gas inlet 95 into the plasma generator 91. The second gas outlet 97 may be connected to another end of the plasma generator 91. A gas may be released through the second gas outlet 97 from the plasma generator 91. The cooling water inlet 92 may be connected to the plasma generator 91. Cooling water may be introduced through the cooling water inlet 92 into the plasma generator 91. The cooling water outlet 94 may be connected to the plasma generator 91. The cooling water may be released through the cooling water outlet 94 from the plasma generator 91.

Referring to FIG. 11, the plasma generator 91 may include an inner electrode 911, an outer electrode 913, and a cooling line 917.

The inner electrode 911 may extend in the first direction D1. In some embodiments, the inner electrode 911 may have a cylindrical shape. The inner electrode 911 may include steel, but embodiments are not limited thereto.

The outer electrode 913 may extend in the first direction D1. The outer electrode 913 may have a cylindrical shape. The outer electrode 913 may surround the inner electrode 911. The outer electrode 913 may include steel, but embodiments are not limited thereto. An inner surface of the outer electrode 913 may be outwardly spaced apart from an outer surface of the inner electrode 911. Therefore, a gas treatment path 91h1 may be provided between the inner electrode 911 and the outer electrode 913. The gas treatment path 91h1 may be connected to the second exhaust line (for example, the second exhaust line 17 of FIG. 9) through the second gas inlet (for example, the second gas inlet 95 of FIG. 10) and the second gas outlet (for example, the second gas outlet 97 of FIG. 10).

A dielectric layer 915 may extend in the first direction D1. The dielectric layer 915 may have a cylindrical shape. The dielectric layer 915 may be positioned between the inner electrode 911 and the outer electrode 913. For example, the dielectric layer 915 may be combined with the outer electrode 913. The dielectric layer 915 may include ceramic and/or quartz, but embodiments are not limited thereto.

The cooling line 917 may extend in the first direction D1. The cooling line 917 may surround the outer electrode 913. An inner surface of the cooling line 917 may be spaced apart from an outer surface of the outer electrode 913. Therefore, a cooling path 91h2 may be provided between the cooling line 917 and the outer electrode 913. One end of the cooling path 91h2 may be connected to the cooling water inlet (for example, the cooling water inlet 92 of FIG. 10). Another end of the cooling path 91h2 may be connected to the cooling water outlet (for example, the cooling water outlet 94 of FIG. 10). Cooling water may flow along the cooling path 91h2. The cooling water may cool the outer electrode 913.

According to a semiconductor process system and a gas treatment method in accordance with some embodiments, various kinds of plasma processing apparatus may be used to treat an exhaust gas.

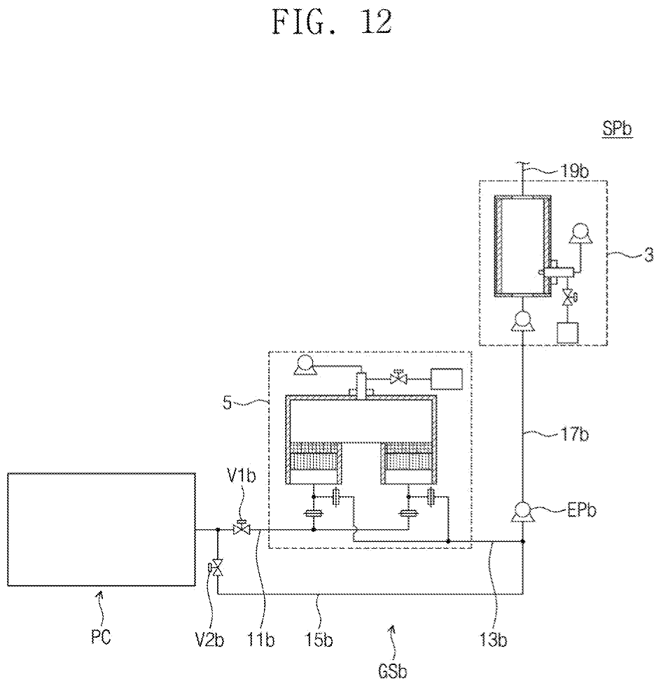

FIG. 12 illustrates a schematic diagram showing a semiconductor process system according to some embodiments.

In the following, redundant or duplicative description which is substantially the same as, or similar to, description provided above with reference to FIGS. 1 to 11 may be omitted.

Referring to FIG. 12, a semiconductor process system SPb may be provided. The semiconductor process system SPb may include a semiconductor process chamber PC and a gas treatment system GSb.

The gas treatment system GSb may be associated with the semiconductor process chamber PC. The gas treatment system GSb may treat a gas discharged from the semiconductor process chamber PC. For example, the gas treatment system GSb may treat a low-concentration VOC discharged from the semiconductor process chamber PC. The gas treatment system GSb may include a connection line 11b, a thermal oxidizer 5, a first valve V1b, a plasma processing apparatus 3, a first exhaust line 13b, a bypass line 15b, a second valve V2b, a second connection line 17b, and a second exhaust line 19b.

The connection line 11b, the thermal oxidizer 5, and the first valve V1b may be substantially the same as or similar to those discussed with reference to FIG. 1.

The plasma processing apparatus 3 may include a plasma torch oxidizer or a DBD plasma reactor. The following is used to illustrate and describe an example in which a plasma torch oxidizer is used as the plasma processing apparatus 3, but embodiments are not limited thereto. The plasma processing apparatus 3 may be connected in series to the thermal oxidizer 5. For example, the semiconductor process chamber PC, the thermal oxidizer 5, and the plasma processing apparatus 3 may be sequentially connected in series to each other. Therefore, an exhaust gas discharged from the semiconductor process chamber PC may sequentially pass through the thermal oxidizer 5 and the plasma processing apparatus 3. The first exhaust line 13b may connect the thermal oxidizer 5 and the plasma processing apparatus 3 to each other.

The bypass line 15b may be used to bypass the thermal oxidizer 5. For example, one end of the bypass line 15b may be connected to the connection line 11b, and another end of the bypass line 15b may be connected to the second connection line 17b. When an exhaust gas discharged from the semiconductor process chamber PC is introduced into the bypass line 15b, the exhaust gas may enter the plasma processing apparatus 3 without passing through the thermal oxidizer 5.

The second valve V2b may be positioned on the bypass line 15b. The second valve V2b may be opened or closed to control a flow of the exhaust gas from the semiconductor process chamber PC to the bypass line 15b. The second valve V2b may be an automatic valve, but embodiments are not limited thereto.

The second connection line 17b may connect the plasma processing apparatus 3 to one or both of the first exhaust line 13b and the bypass line 15b. The second exhaust line 19b may be connected to the plasma processing apparatus 3. The second exhaust line 19b may outwardly discharge the exhaust gas that has been treated in the plasma processing apparatus 3.

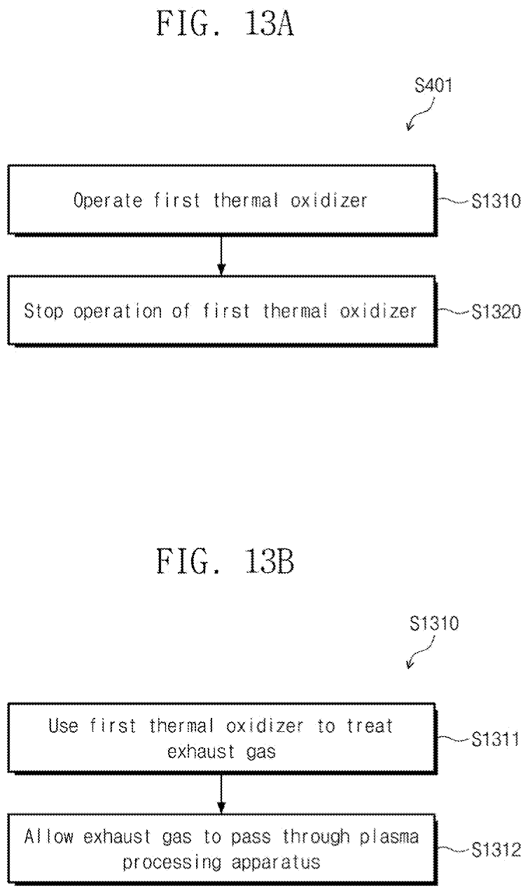

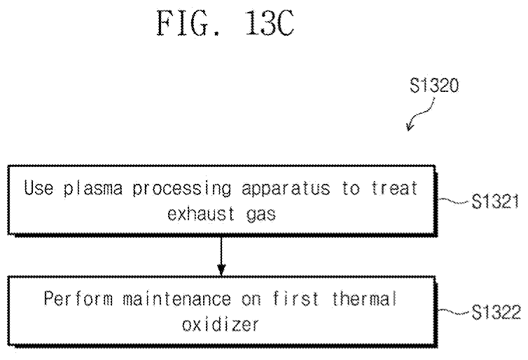

FIGS. 13A to 13C illustrate a flow charts showing example operations which may be used in a gas treatment method according to some embodiments.

FIG. 13A shows an example of operation S401, according to embodiments. For example, the operations illustrated in FIG. 13A may be used to perform the method 400 discussed with reference to FIG. 4A, using the gas treatment system GSb discussed with reference to FIG. 12.

As shown in FIG. 13A, operation 401 operating a first thermal oxidizer at operation S1310, and stopping the first thermal oxidizer at operation S1320.

As shown in FIG. 13B, operation S1310 may include allowing the first thermal oxidizer to treat the exhaust at operation S1311 and allowing the exhaust gas to pass through a plasma processing apparatus at operation S1312.

As shown in FIG. 13C, operation S1320 may include allowing the plasma processing apparatus to treat the exhaust gas at operation S1321 and performing maintenance on the first thermal oxidizer at operation S1322.

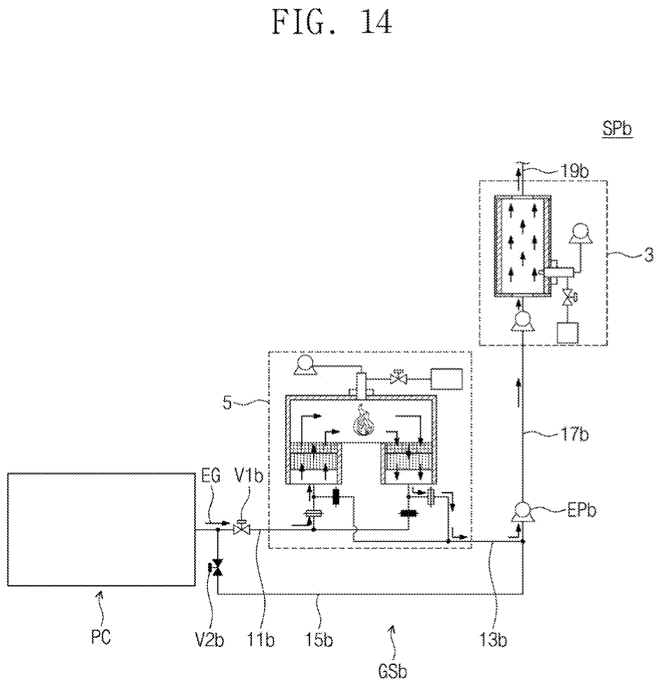

The example of operation 401 illustrated in FIG. 13 is discussed below with reference to FIGS. 14 to 19.

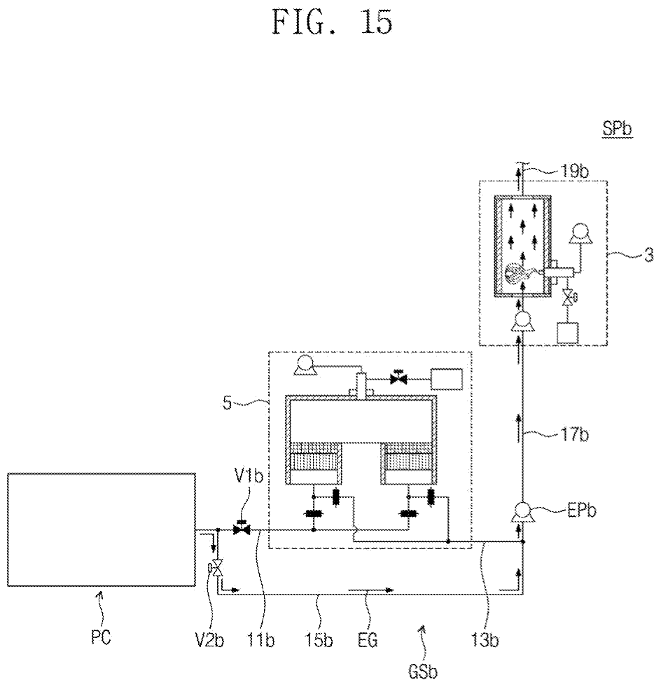

FIGS. 14 and 15 illustrate diagrams showing example operations of a gas treatment method according to the flow charts of FIG. 4A and FIGS. 13A to 13C.

Referring to FIGS. 13A to 13C and 14, operation S1311 may include allowing an exhaust gas EG to enter the thermal oxidizer 5 through the connection line 11b and the first valve V1b from the semiconductor process chamber PC. The thermal oxidizer 5 may operate to treat the exhaust gas EG. The exhaust gas EG treated in the thermal oxidizer 5 may be discharged through the first exhaust line 13b.

Operation S1312 may include allowing the exhaust gas EG that has passed through the thermal oxidizer 5 to enter the plasma processing apparatus 3 through the first exhaust line 13b and the second connection line 17b. In operation S1312, the plasma processing apparatus 3 may not be operated. For example plasma processing apparatus 3 may not form a flame or flames. The exhaust gas EG may pass through the plasma processing apparatus 3 that is not being operated. Because harmful substances in the exhaust gas EG are treated in the thermal oxidizer 5, it may not be required to operate the plasma processing apparatus 3. Therefore, when the thermal oxidizer 5 operates, not operating the plasma processing apparatus 3 may save power.

Referring to FIGS. 13 and 15, the step S1321 may include allowing the thermal oxidizer 5 to be bypassed by the exhaust gas EG discharged from the semiconductor process chamber PC. For example, the exhaust gas EG discharged from the semiconductor process chamber PC may move along the bypass line 15b to bypass the thermal oxidizer 5. The exhaust gas EG may move to the plasma processing apparatus 3 without passing through the thermal oxidizer 5. The thermal oxidizer 5 may not be operated during operation S1321. For example, the thermal oxidizer 5 may not form a flame or flames.

Operation S1322 may include performing maintenance on the thermal oxidizer 5 that is not being operated. For example, a heat storage medium in the thermal oxidizer 5 may be replaced and/or maintained.

According to a semiconductor process system and a gas treatment system in accordance with some embodiments, a thermal oxidizer and a plasma processing apparatus may be connected in series to each other. In this case, a bypass line may be installed which bypasses the thermal oxidizer. Therefore, when the thermal oxidizer needs maintenance, an exhaust gas discharged from a semiconductor process chamber may be bypassed and directed to the plasma processing apparatus. Accordingly, harmful substances in the exhaust gas may be eliminated even during maintenance of the thermal oxidizer.

According to a semiconductor process system and a gas treatment system in accordance with some embodiments, a thermal oxidizer and a plasma processing apparatus may be connected in series to each other and thus a simplified line configuration may be accomplished.

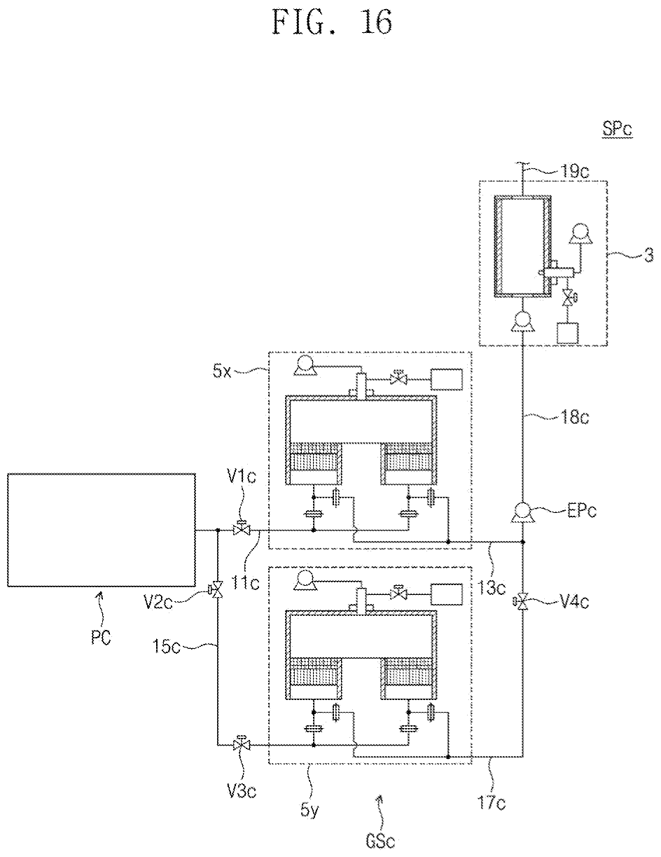

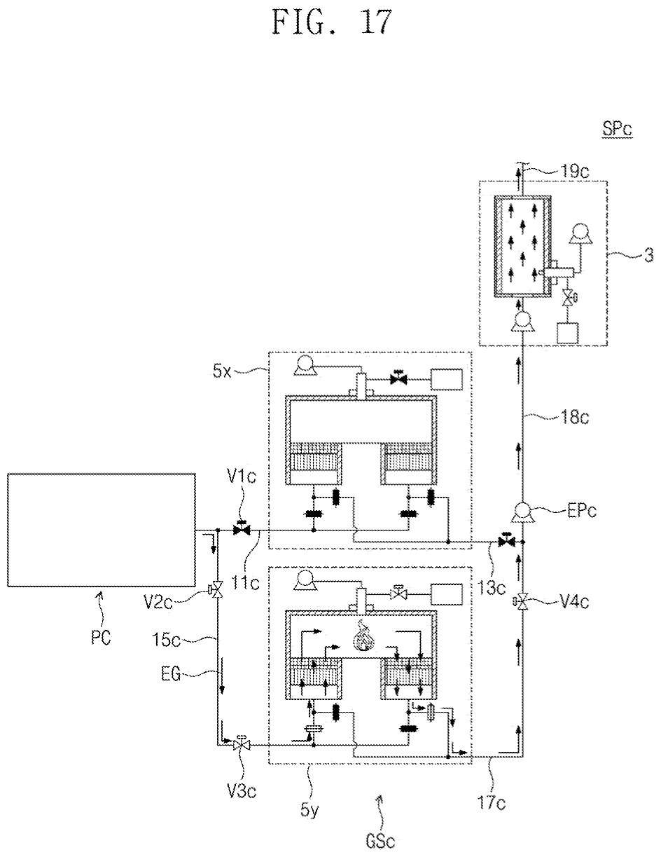

FIG. 16 illustrates a schematic diagram showing a semiconductor process system according to some embodiments.

In the following, redundant or duplicative description of components which are substantially the same as or similar to those discussed above with reference to FIGS. 1 to 15 may be omitted.

Referring to FIG. 16, a semiconductor process system SPc may be provided. The semiconductor process system SPc may include a semiconductor process chamber PC and a gas treatment system GSc.

The gas treatment system GSc may be associated with the semiconductor process chamber PC. The gas treatment system GSc may treat a gas discharged from the semiconductor process chamber PC. For example, the gas treatment system GSc may treat a low-concentration VOC discharged from the semiconductor process chamber PC. The gas treatment system GSc may include a first connection line 11c, a first thermal oxidizer 5x, a first valve Vic, a first exhaust line 13c, a second connection line 15c, a second thermal oxidizer 5y, a second valve V2c, a third valve V3c, a second exhaust line 17c, a fourth valve V4c, a third connection line 18c, a plasma processing apparatus 3, and a fourth exhaust line 19c.

The first thermal oxidizer 5x and the second thermal oxidizer 5y may be connected to the semiconductor process chamber PC in parallel to each other. For example, the first thermal oxidizer 5x and the second thermal oxidizer 5y may be disposed in parallel to each other with respect to the semiconductor process chamber PC. Therefore, an exhaust gas discharged from the semiconductor process chamber PC may move to only one of the first thermal oxidizer 5x and the second thermal oxidizer 5y.

The plasma processing apparatus 3 may include a plasma torch oxidizer or a DBD plasma reactor. The following is used to illustrate and describe an example in which a plasma torch oxidizer is used as the plasma processing apparatus 3, but embodiments are not limited thereto. The plasma processing apparatus 3 may be connected in series to the first thermal oxidizer 5x. For example, the semiconductor process chamber PC, the first thermal oxidizer 5x, and the plasma processing apparatus 3 may be sequentially connected in series to each other. Therefore, the exhaust gas discharged from the semiconductor process chamber PC may sequentially pass through the first thermal oxidizer 5x and the plasma processing apparatus 3.

FIGS. 17 to 19 illustrate diagrams showing example operations of the gas treatment method according to the flow charts of FIG. 4A and FIGS. 13A to 13C.

Referring to FIGS. 13C and 17, operation S1321 may include allowing the exhaust gas to pass through a second thermal oxidizer. For example, before operation S1321 is performed, an exhaust gas EG may be treated while passing through the second thermal oxidizer 5y. The first thermal oxidizer 5x may not be operated while the exhaust gas EG is treated using the second thermal oxidizer 5y. Accordingly, maintenance may be performed on the first thermal oxidizer 5x. The exhaust gas EG that has been treated in the second thermal oxidizer 5y may pass through the plasma processing apparatus 3. In embodiments, the plasma processing apparatus 3 may be not operated while the second thermal oxidizer 5y is operated.

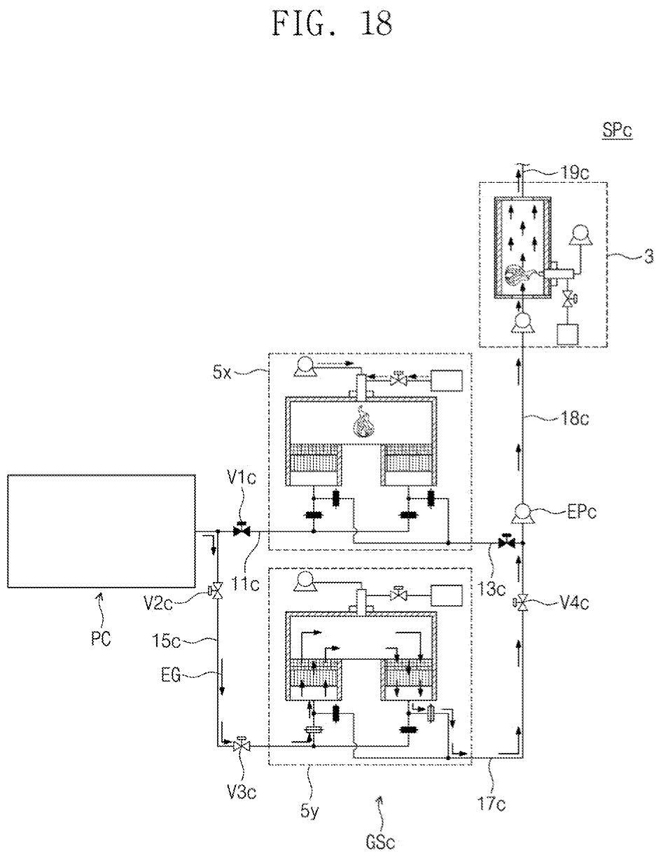

Referring to FIG. 18, in operation S1321 the exhaust gas EG may pass through the second thermal oxidizer 5y. The second thermal oxidizer 5y may not be operated in operation S1321. For example, the second thermal oxidizer 5y may not form a flame or flames. Therefore, the second thermal oxidizer 5y may not burn the exhaust gas EG. The exhaust gas EG that has passed through the second thermal oxidizer 5y may be burned in the plasma processing apparatus 3. For example, the plasma processing apparatus 3 may form a flame or flames to burn the exhaust gas EG. The first thermal oxidizer 5x may be pre-heated during operation S1321. The exhaust gas EG discharged from the semiconductor process chamber PC may not pass through the first thermal oxidizer 5x, but the first thermal oxidizer 5x may form a flame or flames. Accordingly, the first thermal oxidizer 5x may be pre-heated to finish preparation for treatment of the exhaust gas EG.

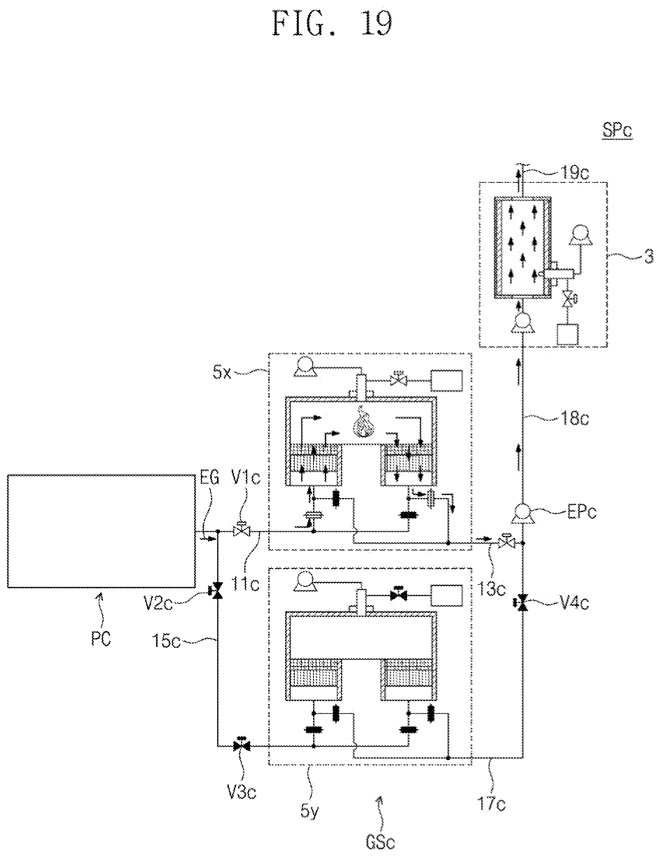

Referring to FIG. 19, the exhaust gas EG discharged from the semiconductor process chamber PC may be introduced into the first thermal oxidizer 5x that has been pre-heated. The first thermal oxidizer 5x may form a flame or flames to burn the exhaust gas EG. The exhaust gas EG that has been treated in the first thermal oxidizer 5x may pass through the plasma processing apparatus 3.

According to a semiconductor process system and a gas treatment method in accordance with some embodiments, two thermal oxidizers may be used. Thus, while one of the two thermal oxidizers is used, maintenance may be performed on the other of the two thermal oxidizers. In addition, the thermal oxidizer may be pre-heated while an exhaust gas does not pass through. It may thus be possible to perform preparation for treatment of an exhaust gas.

According to a semiconductor process system and a gas treatment method, an exhaust gas may be treated even during maintenance of a thermal oxidizer.

According to a semiconductor process system and a gas treatment method, it may be possible to save power.

According to a semiconductor process system and a gas treatment method, it may be possible to prevent release of harmful substances even in case of emergency.

Effects are not limited to the mentioned above, other effects which have not been mentioned above will be clearly understood to those skilled in the art from the following description.

Although embodiments have been described in connection with some embodiments illustrated in the accompanying drawings, it will be understood to those skilled in the art that various changes and modifications may be made without departing from the technical spirit and essential feature. It therefore will be understood that the embodiments described above are just illustrative but not limitative in all aspects.

What is claimed is:

1. A gas treatment method, comprising:
treating an exhaust gas discharged from a semiconductor process chamber using a gas treatment system; and
discharging the treated exhaust gas,
wherein the treating the exhaust gas comprises:
operating a first thermal oxidizer to treat the exhaust gas discharged from the semiconductor process chamber, the first thermal oxidizer being connected to the semiconductor process chamber, and allowing the treated exhaust gas to pass through a plasma processing apparatus connected to the first thermal oxidizer; and
stopping the operation of the first thermal oxidizer to perform maintenance on the first thermal oxidizer,
wherein the stopping the operation of the first thermal oxidizer comprises:
performing maintenance on the first thermal oxidizer; and
operating the plasma processing apparatus to treat the exhaust gas discharged from the semiconductor process chamber.

2. The gas treatment method of claim 1, wherein the stopping the operation of the first thermal oxidizer further comprises allowing the exhaust gas discharged from the semiconductor process chamber to bypass the first thermal oxidizer.

3. The gas treatment method of claim 2, wherein the stopping the operation of the first thermal oxidizer further comprises performing the maintenance on the first thermal oxidizer while the exhaust gas bypasses the first thermal oxidizer.

4. The gas treatment method of claim 3, wherein the maintenance comprises replacing a heat storage medium of the first thermal oxidizer.

5. The gas treatment method of claim 2, wherein the allowing the exhaust gas to bypass the first thermal oxidizer comprises allowing the exhaust gas discharged from the semiconductor process chamber to pass through a second thermal oxidizer connected to the semiconductor process chamber in parallel with the first thermal oxidizer.

6. The gas treatment method of claim 1, wherein the stopping the operation of the first thermal oxidizer further comprises allowing the exhaust gas to pass through the first thermal oxidizer without burning the exhaust gas using the first thermal oxidizer.

7. The gas treatment method of claim 1, wherein the stopping the operation of the first thermal oxidizer further comprises pre-heating the first thermal oxidizer while the exhaust gas passes through a second thermal oxidizer connected to the semiconductor process chamber in parallel with the first thermal oxidizer.

8. The gas treatment method of claim 1, wherein the plasma processing apparatus is not operated during the operation of the first thermal oxidizer.

9. The gas treatment method of claim 1, wherein the plasma processing apparatus comprises at least one of a plasma torch oxidizer and a dielectric barrier discharge (DBD) plasma reactor.

10. The gas treatment method of claim 1, wherein the first thermal oxidizer comprises a regenerative catalytic oxidizer (RCO).

11. A gas treatment method, comprising:
treating an exhaust gas discharged from a semiconductor process chamber using a gas treatment system; and
discharging the treated exhaust gas,
wherein the treating the exhaust gas comprises:
operating a first thermal oxidizer to treat the exhaust gas discharged from the semiconductor process chamber, the first thermal oxidizer being connected to the semiconductor process chamber; and
operating a plasma processing apparatus to treat the exhaust gas discharged from the semiconductor process chamber, the plasma processing apparatus being connected to the semiconductor process chamber in parallel to the first thermal oxidizer.

12. The gas treatment method of claim 11, wherein the first thermal oxidizer comprises a regenerative catalytic oxidizer (RCO),
wherein the operating the first thermal oxidizer comprises:
heating the exhaust gas while the exhaust gas passes through a heat storage medium;
allowing the exhaust gas to pass through a catalytic layer after the exhaust gas passes through the heat storage medium; and
heating the exhaust gas using a combustion chamber after the exhaust gas passes through the catalytic layer.

13. The gas treatment method of claim 11, wherein the plasma processing apparatus comprises a plasma torch oxidizer, and
wherein the operating of the plasma processing apparatus comprises igniting a plasma torch to burn the exhaust gas in the plasma torch oxidizer.

14. The gas treatment method of claim 11, wherein the plasma processing apparatus comprises a dielectric barrier discharge (DBD) plasma reactor, and
wherein the operating the plasma processing apparatus comprises allowing plasma generated by the DBD plasma reactor to treat the exhaust gas in the DBD plasma reactor.

15. The gas treatment method of claim 11, wherein the operating of the plasma processing apparatus comprises:
stopping the operating of the first thermal oxidizer; and
performing maintenance on the first thermal oxidizer.

16. The gas treatment method of claim 11, wherein the plasma processing apparatus is not operated during the operating of the first thermal oxidizer.

17. A semiconductor process system, comprising:
a semiconductor process chamber; and
a gas treatment system configured to treat an exhaust gas discharged from the semiconductor process chamber,
wherein the gas treatment system comprises:
a thermal oxidizer configured to treat the exhaust gas discharged from the semiconductor process chamber, the thermal oxidizer being connected to the semiconductor process chamber; and
a plasma processing apparatus configured to treat the exhaust gas discharged from the semiconductor process chamber.

18. The semiconductor process system of claim 17, wherein the plasma processing apparatus comprises at least one of a plasma torch oxidizer and a dielectric barrier discharge (DBD) plasma reactor.

19. The semiconductor process system of claim 17, wherein the plasma processing apparatus is connected to the semiconductor process chamber in parallel with the thermal oxidizer.

20. The semiconductor process system of claim 17, wherein the plasma processing apparatus is connected to the thermal oxidizer such that the thermal oxidizer is between the semiconductor process chamber and the plasma processing apparatus.
